(19) United States
(12) Patent Application Publication
(10) Pub. No.: US 2006/0231944 A1
(43) Pub. Date: Oct. 19, 2006

(54) Thermally enhanced semiconductor package and fabrication method thereof

(75) Inventors: Chien Ping Huang, Taichung (TW); Chih Ming Huang, Taichung (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/404,674

(22) Filed: Apr. 14, 2006

(30) Foreign Application Priority Data
Apr. 15, 2005 (TW) 094111973

(51) Int. Cl. H01L 23/34

(52) U.S. Cl. 257/706; 438/122; 438/125; 257/E23.081

(57) ABSTRACT

A thermally enhanced semiconductor package and a fabrication method thereof are provided. A semiconductor chip is mounted and electrically connected to a chip carrier. A receiving plate having an opening is provided on the chip carrier and the semiconductor chip is received in the opening. A heat sink formed with an interface layer on a surface thereof is attached via another surface thereof to the semiconductor chip. An encapsulant encapsulating the heat sink, the semiconductor chip and a portion of the receiving plate is formed. A cutting process is performed to cut along edges of the opening of the receiving plate to remove the receiving plate and a portion of the encapsulant formed on the receiving plate. A portion of the encapsulant formed on the interface layer is removed. This allows heat produced by the semiconductor chip to be effectively dissipated by the heat sink.

### FIELD OF THE INVENTION

The present invention relates to semiconductor packages and fabrication methods thereof, and more particularly, to a semiconductor package having a heat sink for effectively dissipating heat, and a fabrication method of the semiconductor package.

### BACKGROUND OF THE INVENTION

Semiconductor package with a reduced integrated circuit (IC) area and high density of pins, such as ball grid array (BGA) package, has been widely applied to light-weight and small-profile electronic products. Such semiconductor package advantageously having high density of electronic circuits and electronic components produces relatively more heat during operation accordingly. However, as an encapsulant poor in thermal conductivity is used for encapsulating a semiconductor chip incorporated in the semiconductor package, the heat cannot be efficiently dissipated via the encapsulant, making the performance of the chip undesirably affected.

There has been proposed mounting a heat sink (or also referred to as heat slug or heat block) in the semiconductor package to enhance the heat dissipating efficiency, as disclosed in, for example, U.S. Pat. Nos. 5,216,278; 5,736,785; 5,977,626; 6,522,428; 6,528,876; 6,462,405; 6,429,512; 6,433,420; 6,444,498; and 6,458,626.

FIG. 7 shows a semiconductor package with a heat sink as disclosed in U.S. Pat. No. 5,977,626. The heat sink 71 is mounted on a substrate 73 of the semiconductor package, wherein a central protruded portion 711 of the heat sink 71 is in contact with a semiconductor chip 70, and a top surface 710 of the heat sink 71 is exposed from an encapsulant 74, such that heat generated during operation of the chip 70 can be dissipated via the heat sink 71.

However, there are several drawbacks incurred during fabrication of the above semiconductor package. First, when the heat sink 71 is attached to the chip 70 and is placed in a mold cavity during a molding process for forming the encapsulant 74, the top surface 710 of the heat sink 71 must abut against a top wall of the mold cavity; otherwise, the encapsulant 74 would flash over the top surface 710 of the heat sink 71 if there is a gap between the top surface 710 and the top wail of the mold cavity. The flashes formed on the heat sink 71 undesirably degrade the heat dissipating efficiency and impair the appearance of the fabricated product, such that a deflash process is often required to remove the flashes. However, the deflash process is time-consuming and cost-ineffective to implement and may also cause damage to the fabricated product. On the other hand, if the top surface 710 of the heat sink 71 over strongly abuts against the top wall of the mold cavity, the chip 70 may be cracked due to the excessive pressure.

Moreover, in order to have a distance between the top surface 710 of the heat sink 71 and an upper surface of the substrate 73 just equal to a depth of the mold cavity, it requires precise control on attachment between the heat sink 71 and the chip 70, attachment between the chip 70 and the substrate 73, and a thickness of the heat sink 71, thereby increasing costs and process complexity and having difficulty in implementation. U.S. Pat. Nos. 5,216,278 and 5,736,785 have also disclosed similar semiconductor packages, which thus face the same problems in fabrication as mentioned above.

In light of the above drawbacks, U.S. Pat. Nos. 6,522,428; 6,528,876; 6,462,405; 6,429,512; and 6,433,420 have disclosed a semiconductor package having a heat sink not in contact with a semiconductor chip. As shown in FIG. 8 of the semiconductor package disclosed in U.S. Pat. No. 6,462,405, the semiconductor chip 80 is electrically connected to a substrate 83 via bonding wires 82, and a spacer 85 made of e.g. a defective chip is mounted on an upper surface of the chip 80. The heat sink 81 is mounted on the substrate 83 and has a top surface thereof being exposed from an encapsulant 84. The heat sink 81 is formed with a recess 811 where the chip 80 is placed without in contact with the heat sink 81, so as to prevent cracks of the chip 80 due to pressure from the heat sink 81 during a molding process. However, with no contact between the heat sink 81 and the chip 80, the heat sink 81 cannot efficiently dissipate heat produced by the chip 80, making reliability of the chip 80 degraded and not meeting the heat dissipation requirement for a high-heat-generating integrated circuit. Moreover, such semiconductor package still encounters the problem of flashes on a top surface of the heat sink 81 during the molding process and the problem of requiring precise control to make a distance between the top surface of the heat sink 81 and an upper surface of the substrate 83 just equal to a depth of a mold cavity.

Accordingly, U.S. Pat. Nos. 6,444,498 and 6,458,626 have disclosed a fabrication method of a semiconductor package allowing a heat sink to come into contact with a semiconductor chip without causing cracks of the chip during a molding process.

FIGS. 9A to 9C show the fabrication method of the semiconductor package as disclosed in U.S. Pat. No. 6,444,498. As shown in FIG. 9A, a material layer 95 (such as a tape made of polyimide resin), which has poor adhesion with the heat sink 91, is formed on a surface of the heat sink 91 exposed to the atmosphere. Next, the beat sink 91 is directly attached to the chip 90 mounted on a substrate module plate 93. Then, a molding process is performed to form an encapsulant 94 that encapsulates the heat sink 91 and the chip 90 completely and covers the material layer 95 on the heat sink 91. During the molding process, a depth of a mold cavity of a mold is larger than the sum of thickness of the chip 90 and the heat sink 91, such that the mold after engagement would not come into contact with the heat sink 91, thereby preventing the chip 90 from being cracked by pressure. Subsequently, as shown in FIG. 9B, a singulation process is performed. Finally, as shown in FIG. 9C, a portion of the encapsulant 94 formed on the heat sink 91 is removed, wherein since the material layer 95 has greater adhesion with the encapsulant 94 than with the heat sink 91, when stripping off the portion of the encapsulant 94 on the heat sink 91, the material layer 95 attached to the encapsulant 94 is also removed along with the encapsulant 94 being stripped off, such that no flashes occur on the heat sink 91.

However, the above fabrication method is merely suitable for a thin fine ball grid array (TFBGA) semiconductor package (i.e. a semiconductor package having an encapsulant sized equal in area to a substrate), but is not applicable to other semiconductor packages such as a plastic ball grid array (PBGA) semiconductor package. Therefore, the foregoing technology has very limited applications.

Therefore, the problem to be solved here is to provide a thermally enhanced semiconductor package without having the above drawbacks in the prior art.

### SUMMARY OF THE INVENTION

In light of the foregoing drawbacks in the prior art, an objective of the present invention is to provide a thermally enhanced semiconductor package and a fabrication method thereof, allowing a heat sink to be directly attached to a chip without causing chip cracks and flashes in a molding process, so as to improve the heat dissipating efficiency and yields of fabricated products.

Another objective of the present invention is to provide a thermally enhanced semiconductor package and a fabrication method thereof, without having a concern about height control on attachment between a heat sink and a chip, thereby reducing packaging costs and improving yields of fabricated products.

A further objective of the present invention is to provide a thermally enhanced semiconductor package and a fabrication method thereof, which can enhance industrial applicability thereof.

In accordance with the above and other objectives, the present invention proposes a thermally enhanced semiconductor package and a fabrication method thereof. The fabrication method of the thermally enhanced semiconductor package includes the steps of: mounting and electrically connecting at least one semiconductor chip to a chip carrier, wherein a receiving plate having an opening corresponding in position to the chip is mounted on the chip carrier, and the semiconductor chip is received in the opening and mounted on the chip carrier; attaching a surface of a heat sink to the semiconductor chip, wherein an interface layer is formed on another surface of the heat sink; performing a molding process to form an encapsulant for encapsulating the heat sink, the semiconductor chip and a portion of the receiving plate; performing a cutting process along edges of the opening of the receiving plate to remove the receiving plate and a portion of the encapsulant formed on the receiving plate; and removing a portion of the encapsulant formed on the interface layer on the heat sink.

The chip carrier can be a BGA substrate or a LGA (land grid array) substrate, and the semiconductor chip can be electrically connected to the substrate by bonding wires or in a flip-chip manner. If the chip carrier is a BGA substrate, the above fabrication method further includes a step of performing a ball implantation process to form a plurality of conductive elements for allowing the semiconductor chip to be electrically connected to an external device. Moreover, the semiconductor package can be fabricated in a batch-type manner, and the ball implantation process can be performed before or after a singulation process.

The opening of the receiving plate is sized substantially equal in area to the encapsulant after completing the molding process and the cutting process. The heat sink is sized larger in area than the opening of the receiving plate, such that the heat sink is also cut in the cutting process where cutting is performed along the edges of the opening of the receiving plate, and side surfaces of the heat sink are exposed from the encapsulant after the cutting process. The heat sink may be formed with recessed portions at positions corresponding to the edges of the receiving plate where cutting is to be performed, such that the heat sink becomes thinner at the cutting positions, making the cutting process easier to be carried out. After the cutting process, a remaining portion of the encapsulant has an area equal to or smaller than that of the opening of the receiving plate. A bottom surface of the heat sink, or the surface thereof attached to the semiconductor chip, is formed with an adhesion-enhanced portion at a position in contact with the encapsulant, wherein the adhesion-enhanced portion can be a convex-concave structure, a roughened structure, and a structure subjected to a black oxide process.

The interface layer can be a metal layer which have greater adhesion with the heat sink than with the encapsulant, such that the interface layer remains on the heat sink after the portion of the encapsulant on the interface layer is removed for example by stripping. Also due to the poor adhesion between the interface layer and the encapsulant, there would be no residue of the encapsulant left on the interface layer after the portion of the encapsulant on the interface layer is removed, thus not having a flash problem. Alternatively, the interface layer can be an adhesive tape made of polyimide resin which have smaller adhesion with the heat sink than with the encapsulant, such that the interface layer would be removed together with the encapsulant when the portion of the encapsulant on the interface layer is stripped off, thereby not having flashes on the heat sink.

The thermally enhanced semiconductor package in the present invention includes: a substrate; a semiconductor chip mounted on an upper surface of the substrate and electrically connected to the substrate; a heat sink mounted on the semiconductor chip; and an encapsulant for encapsulating the semiconductor chip and exposing a top surface and side surfaces of the heat sink, wherein edges of the encapsulant are flush with the side surfaces of the heat sink, and the encapsulant has a smaller area than that of the substrate.

The substrate can be a BGA substrate or a LGA substrate, and has a larger area than that of the heat sink and the encapsulant. The semiconductor chip can be electrically connected to the substrate by a wire-bonding or flip-chip technique. A recessed portion can be formed on the heat sink at a position predetermined for cutting (e.g. at an edge of the heat sink), so as to facilitate a subsequent cutting process. Moreover, an adhesion-enhanced portion can be formed on a bottom surface of the heat sink at a position in contact with the encapsulant, and may be a convex-concave structure, a roughened structure or a structure subjected to a black oxide process.

In a preferred embodiment, the semiconductor package further includes an interface layer formed on the heat sink, wherein the interface layer is a metal layer. In another preferred embodiment, the semiconductor package further includes a plurality of conductive elements mounted to a lower surface of the substrate, for allowing the semiconductor chip to be electrically connected to an external device via the conductive elements. The conductive elements are preferably solder balls.

In the present invention, a mold cavity of a mold used in a molding process for forming the encapsulant is sized sufficiently to accommodate the heat sink therein and does not come into contact with the heat sink. Thus, compared with the prior art, the semiconductor package of the present invention may have high heat dissipating efficiency by having the heat sink in direct contact with the semiconductor chip, but prevents cracks of the semiconductor chip due to pressure from the mold or the heat sink, such that the present invention provides a thermally enhanced semiconductor package and a fabrication method thereof without causing cracks of the semiconductor chip. Moreover, the heat sink is formed with an interface layer thereon, and the interface layer allows the portion of the encapsulant formed on the interface layer to be removed easily, thereby eliminating flashes on the beat sink. Further in the semiconductor package, the edges of the encapsulant are flush with the side surfaces of the heat sink, and the heat sink and the encapsulant respectively have a smaller area than that of the substrate.

There is no difficulty in implementing the fabrication method of the thermally enhanced semiconductor package in the present invention, such that the problems such as reduced reliability and quality due to chip cracks in the prior art are avoided and industrial applicability is improved in the present invention. Moreover, the present invention can be applied to different types of semiconductor packages without being limited to the TFBGA structure, thereby having flexible and wide applications and overcoming the drawbacks in the prior art.

### BRIEF DESCRIPTION OF THE DRAWINGS

The invention can be more fully understood by reading the following detailed description of the preferred embodiments, with reference made to the accompanying drawings, wherein:

FIGS. 1A to 1G are schematic diagrams showing steps of a fabrication method of a thermally enhanced semiconductor package according to a first preferred embodiment of the present invention;

FIG. 2 is a schematic diagram of a thermally enhanced semiconductor package according to a second preferred embodiment of the present invention;

FIG. 3 is a schematic diagram of a thermally enhanced semiconductor package according to a third preferred embodiment of the present invention;

FIG. 4 is a schematic diagram of a thermally enhanced semiconductor package according to a fourth preferred embodiment of the present invention;

FIG. 5 is a schematic diagram of a thermally enhanced semiconductor package according to a fifth preferred embodiment of the present invention;

FIG. 6 is a schematic diagram of a thermally enhanced semiconductor package according to a sixth preferred embodiment of the present invention;

FIG. 7 (PRIOR ART) is a schematic diagram of a semiconductor package with a heat sink as disclosed in U.S. Pat. No. 5,977,626;

FIG. 8 (PRIOR ART) is a schematic diagram of a semiconductor package with a heat sink as disclosed in U.S. Pat. No. 6,462,405; and

FIGS. 9A to 9C (PRIOR ART) are schematic diagrams showing steps of a fabrication method of a semiconductor package as disclosed in U.S. Pat. No. 6,444,498.

### DETAILED DESCRIPTION OF PREFERRED EMBODIMENTS

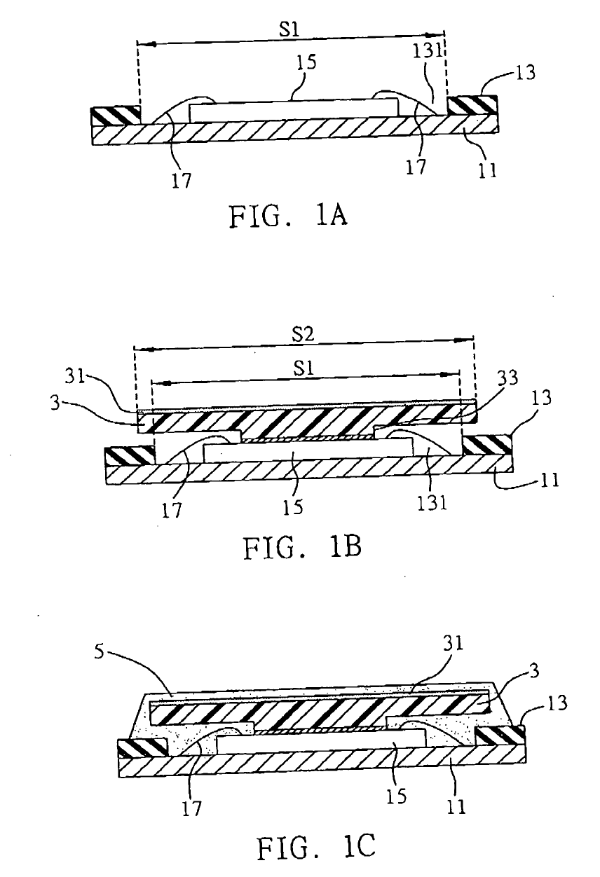

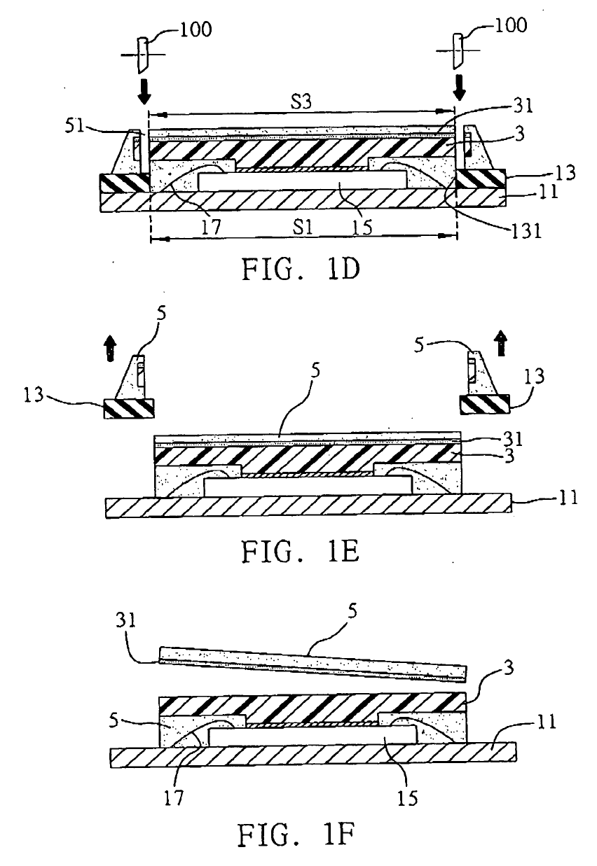

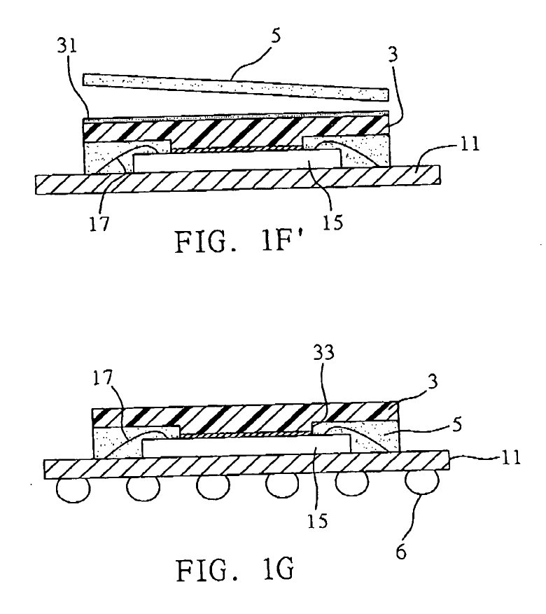

Preferred embodiments of a thermally enhanced semiconductor package and a fabrication method thereof as proposed in the present invention are described as follows with reference to FIGS. 1 to 6. It should be noted that the drawings only show relevant components for the present invention, and the component layout can be more complicated in practical implementation.

### First Preferred Embodiment

FIGS. 1A to 1G show steps of a fabrication method of a thermally enhanced semiconductor package according to a first preferred embodiment of the present invention.

As shown in FIG. 1A, a chip carrier such as a substrate 11 is provided, and at least one semiconductor chip 15 is mounted on and electrically connected to an upper surface of the substrate 11. A receiving plate 13 having at least one opening 131 corresponding in position to the semiconductor chip 15 is mounted on the upper surface of the substrate 11, allowing the semiconductor chip 15 to be received in the opening 131 and mounted on the substrate 11.

The substrate 11 can be a BGA substrate. The receiving plate 13 can be a metal plate made of copper, a PI (polyimide) tape, a BT (bismaleimide triazine) substrate, or made of any other suitable materials. In this embodiment, the opening 131 has a size S1 substantially equal to that of a fabricated package. The semiconductor chip 15 is electrically connected to the substrate 11 by, for example, bonding wires 17.

It should be noted that, the semiconductor chip 15 can first be mounted on the substrate 11 and electrically connected to the substrate 11 by the bonding wires 17, and then the receiving plate 13 is attached to the substrate 11. Alternatively, the receiving plate 13 can first be mounted to the substrate 11, and then the semiconductor chip 15 is placed in the opening 131 of the receiving plate 13 on the substrate 11 and is electrically connected to the substrate 11 by the bonding wires 17.

As shown in FIG. 1B, a heat sink 3 with an interface layer 31 on a surface (e.g. a top surface) thereof is attached via another surface (e.g. a bottom surface) thereof to the semiconductor chip 15. The heat sink 3 can be made of copper, aluminum, copper alloy, aluminum alloy or any other materials having good thermal conductivity.

In this embodiment, the heat sink 3 has, for example, a T-shaped cross-section. The heat sink 3 has a size S2 larger than the size S1 of the opening 131 of the receiving plate 13. A contact portion 33 is formed on the bottom surface of the heat sink 3 and is extended to an upper surface of the semiconductor chip 15, wherein provision of the contact portion 33 keeps the bonding wires 17 from coming into contact with the heat sink 3.

The interface layer 31 can be made by plating gold, chromium or any other metals, which have poor adhesion with an encapsulating compound, on the heat sink 3. The interface layer 31 can also be a tape of polyimide resin attached to the heat sink 3, or a coating layer of epoxy resin coated on the heat sink 3, wherein adhesion between the polyimide tape or the coating layer and the heat sink 3 is smaller than that between the polyimide tape or the coating layer and the encapsulating compound, such that the encapsulating compound can be easily removed from the interface layer 31 in a subsequent process and no flashes occur.

As shown in FIG. 1C, the substrate 11 on which the heat sink 3 and the semiconductor chip 15 are mounted is placed in a mold cavity of a mold (not shown), wherein the heat sink 3 is completely received in the mold cavity and a suitable gap between a top wall of the mold cavity and the heat sink 3 is formed. The encapsulating compound is injected into the mold cavity to form an encapsulant 5 for encapsulating the heat sink 3, the substrate 11, the semiconductor chip 15, the bonding wires 17 and a portion of the receiving plate 13. There is no contact between the mold cavity of the mold and the heat sink 3, such that the semiconductor chip 15 does not suffer pressure from the mold or the heat sink 3 after mold engagement, thereby avoiding chip cracks in the prior art.

As shown in FIGS. 1D and 1E, a cutting process is performed to cut along edges of the opening 131 of the receiving plate 13 such that the receiving plate 13 and a portion of the encapsulate 5 formed on the receiving plate 13 are removed. As shown in FIG. 1D, cutting paths 51 can be defined in advance. A distance S3 between the cutting paths 51 can be equal to the size S1 of the opening 131 of the receiving plate 13. A cutting tool 100 cuts along the cutting paths 51 through the encapsulant 5 and the heat sink 3 to expose the receiving plate 13. Subsequently, as shown in FIG. 1E, the receiving plate 13 and the portion of the encapsulant 5 on the receiving plate 13 are removed.

As shown in FIG. 1F, a portion of the encapsulant 5 formed on the interface layer 31 on the heat sink 3 is removed. If the interface layer 31 (such as a polyimide tape) on the heat sink 3 has smaller adhesion with the heat sink 3 than with the encapsulant 5, the interface layer 31 would be removed together with the encapsulant 5 when the portion of the encapsulant 5 on the interface layer 31 is stripped off (shown in FIG. 1F), such that no flashes occur on the heat sink 3. On the other hand, if the interface layer 31 (such as a gold plated layer) has greater adhesion with the heat sink 3 than with the encapsulant 5, the interface layer 31 would remain on the heat sink 3 after the portion of the encapsulant 5 on the interface layer 31 is stripped off, and there is no residue of the encapsulant 5 left on the interface layer 31 due to the poor adhesion between the interface layer 31 and the encapsulant 5 (shown in FIG. 1F′), such that no flash problem arises.

As shown in FIG. 1G, subsequently, if the substrate 11 is a BGA substrate, a ball implantation process is performed to mount a plurality of conductive elements 6 such as solder balls to a lower surface of the substrate 11 such that the semiconductor chip 15 can be electrically connected to an external device via the conductive elements 6. Thereby, a thermally enhanced semiconductor package is completed. It should be understood that, the semiconductor package can be fabricated in a batch-type manner, and the ball implantation process can be performed prior to a singulation process of cutting along predetermined cutting paths to obtain individual package units, thereby not limited to the disclosure of this embodiment. Since the ball implantation process and the singulation process are well known in the art, they are not to be further detailed herein.

Referring to FIG. 1G, the thermally enhanced semiconductor package fabricated in the present invention includes a substrate 11, a semiconductor chip 15, a heat sink 3, an encapsulant 5 and a plurality of conductive elements 6. The substrate 11 has an upper surface and an opposed lower surface, and has an area larger than that of the heat sink 3 and the encapsulant 5. The substrate 11 can be a BGA substrate. The semiconductor chip 15 is attached to the upper surface of the substrate 11 by an adhesive (not shown) and is electrically connected to the substrate 11 by, for example, bonding wires 17. The heat sink 3 has, for example, a T-shaped cross-section, and is formed with a contact portion 33 that is extended to an upper surface the semiconductor chip 15 and in contact with the semiconductor chip 15. The encapsulant 5 encapsulates the semiconductor chip 15 and exposes a top surface and side surfaces of the heat sink 3, wherein edges of the encapsulant 5 are flush with the side surfaces of the heat sink 3. The conductive elements 6 are mounted to the lower surface of the substrate 11, for allowing the semiconductor chip 15 to be electrical connected to an external device via the conductive elements 6. The conductive elements 6 can be, but not limited to, solder balls.

### Second Preferred Embodiment

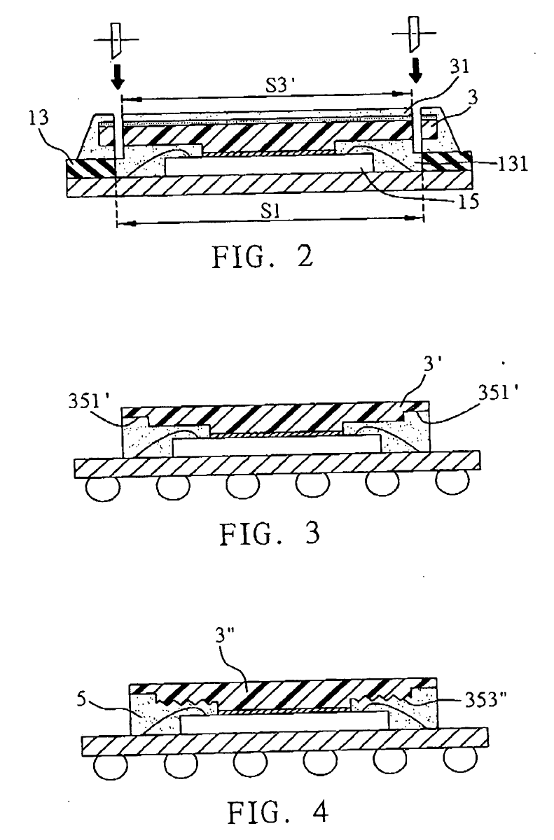

FIG. 2 is a cross-sectional view of a thermally enhanced semiconductor package according to a second preferred embodiment of the present invention, wherein similar or same components in the second embodiment as compared with those in the first embodiment are designated by similar or same reference numerals, and the same parts of structure and fabrication process in the second embodiment as compared with those in the first embodiment are not further repeated here.

A primary difference between the second embodiment and the first embodiment is in that, the distance S3 between the cutting paths along which cutting is performed in the cutting process is equal to the size S1 of the opening of the receiving plate in the first embodiment, whereas in the second embodiment, the distance S3′ between the cutting paths is smaller than the size S1 of the opening of the receiving plate.

As shown in FIG. 2, the cutting paths, instead of along the edges of the opening 131 of the receiving plate 13 in the first embodiment, are defined relatively closer to the semiconductor chip 15 in the second embodiment.

### Third Preferred Embodiment

FIG. 3 is a cross-sectional view of a thermally enhanced semiconductor package according to a third preferred embodiment of the present invention, wherein similar or same components in the third embodiment as compared with those in the foregoing embodiments are designated by similar or same reference numerals, and the same parts of structure and fabrication process in the third embodiment as compared with those in the foregoing embodiments are not further repeated here.

A primary difference between the third embodiment and the foregoing embodiments is in that, in the third embodiment, recessed portions 351′ are formed on the bottom surface of the heat sink 3′ at positions substantially corresponding to edges of the heat sink 3′.

The recessed portions 351′ can be positions near substantially corresponding to the cutting paths described in the foregoing embodiments, such that the cutting tool used in the cutting process only needs to cut a thinner portion of the heat sink 3′ with the recessed portions 351′, thereby further enhancing the cutting efficiency.

### Fourth Preferred Embodiment

FIG. 4 is a cross-sectional view of a thermally enhanced semiconductor package according to a fourth preferred embodiment of the present invention, wherein similar or same components in the third embodiment as compared with those in the foregoing embodiments are designated by similar or same reference numerals, and the same parts of structure and fabrication process in the third embodiment as compared with those in the foregoing embodiments are not further repeated here.

A primary difference between the fourth embodiment and the third embodiment is in that, in the fourth embodiment, an adhesion-enhanced portion 353″ is formed on the bottom surface of the heat sink 3″.

In this embodiment, the adhesion enhanced portion 353″ can be a convex-concave structure to enhance the bonding strength between the heat sink 3″ and the encapsulant 5. Alternatively, the adhesion-enhanced portion 353″ can be a structure formed by performing a roughening process, a black oxide process or any other equivalent processes on the bottom surface of the heat sink 3″ so as to improve the bonding strength between the heat sink 3″ and the encapsulant 5.

### Fifth Preferred Embodiment

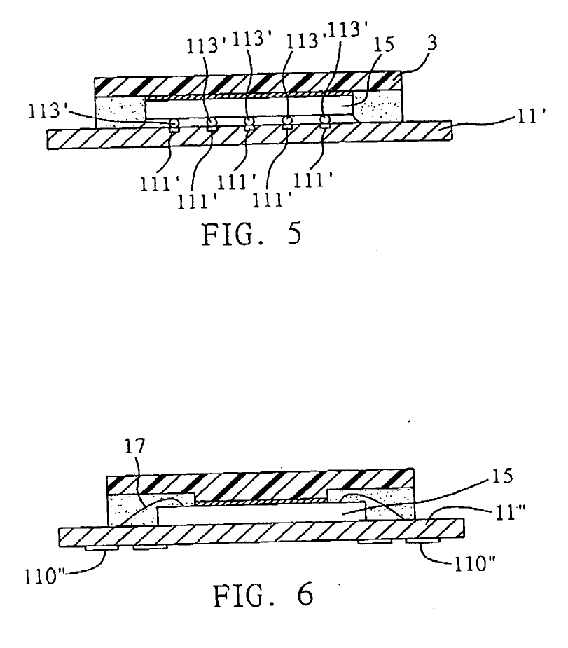

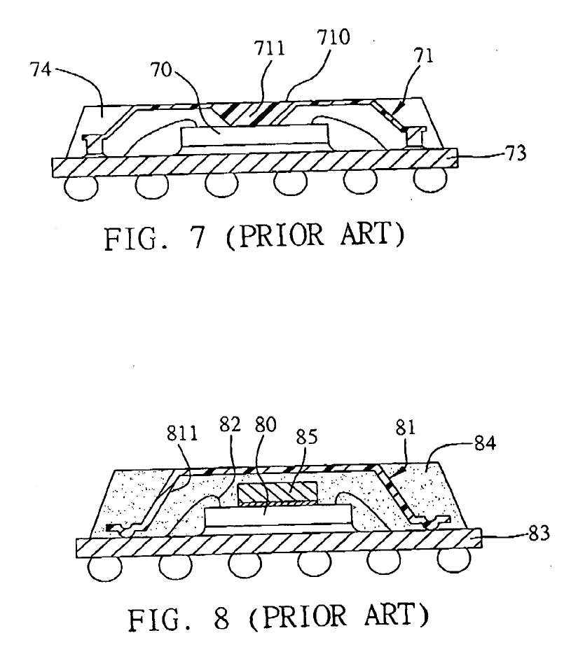

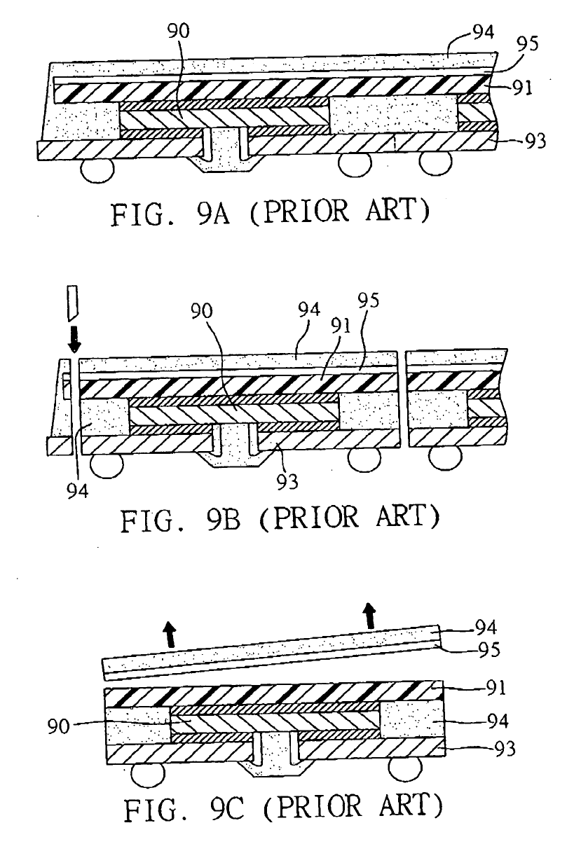

FIG. 5 is a cross-sectional view of a thermally enhanced semiconductor package according to a fifth preferred embodiment of the present invention, wherein similar or same components in the third embodiment as compared with those in the foregoing embodiments are designated by similar or same reference numerals, and the sane parts of structure and fabrication process in the third embodiment as compared with those in the foregoing embodiments are not further repeated here.

A primary difference between the fifth embodiment and the foregoing embodiments is in that, a wire-bonding substrate is used in the foregoing embodiments whereas a flip-chip substrate 11′ is used in the fifth embodiment.

In this embodiment, a plurality of array-arranged bond pads 111′ are formed on the upper surface of the substrate 11′. The semiconductor chip 15 is mounted in a flip-chip manner that an active surface of the semiconductor chip 15 is electrically connected to the bond pads 111′ of the substrate 11′ via solder bumps 113′. The heat sink 3 can be directly attached to a non-active surface of the semiconductor chip 15.

### Sixth Preferred Embodiment

FIG. 6 is a cross-sectional view of a thermally enhanced semiconductor package according to a sixth preferred embodiment of the present invention, wherein similar or same components in the third embodiment as compared with those in the foregoing embodiments are designated by similar or same reference numerals, and the same parts of structure and fabrication process in the third embodiment as compared with those in the foregoing embodiments are not further repeated here.

A primary difference between the sixth embodiment and the foregoing embodiments is in that, the BGA substrate 11 is used in the foregoing embodiments, whereas in the sixth embodiment, a LGA substrate 11″ is used as a chip carrier for carrying the semiconductor chip 15, wherein the non-active surface of the semiconductor chip 15 is mounted to the LGA substrate 11″, and the active surface of the semiconductor chip 15 is electrically connected to the LGA substrate 11″ by bonding wires 17, and further a plurality of metal contacts 110″ are formed on a lower surface of the LGA substrate 11″, for allowing the semiconductor chip 15 to be electrically connected to an external device via the metal contacts 110″.

The present invention allows direct contact between the heat sink and the semiconductor chip without causing chip cracks during the molding process, such that the problems such as degraded reliability and quality due to chip cracks and inefficient heat dissipation in the prior art can be avoided. Moreover, there is no difficulty in implementing the fabrication method of the thermally enhanced semiconductor package in the present invention, and the present invention can be applied to different types of semiconductor packages, such that the drawbacks such as low or limited industrial applicability in the prior art can be eliminated.

Therefore, the present invention provides a thermally enhanced semiconductor package and a fabrication method thereof, which can overcome the drawbacks in the prior art, enhance product reliability together with enhancing the heat dissipating efficiency, and also improve the industrial applicability thereof.

The present invention has been described using exemplary preferred embodiments above, however, it is to be understood that the scope of the present invention is not limited to the disclosed embodiments. On the contrary, it is intended to cover various modifications and similar changes. The scope of the claims, therefore, should be accorded the broadest interpretation so as to encompass all such modifications and similar arrangements.

What is claimed is:

1. A thermally enhanced semiconductor package comprising:
a substrate;
a semiconductor chip mounted on an upper surface of the substrate and electrically connected to the substrate;
a heat sink having a top surface and a bottom surface, with the bottom surface of the heat sink being attached to the semiconductor chip; and
an encapsulant for encapsulating the semiconductor chip and the heat sink, with the top surface and side surfaces of the heat sink being exposed from the encapsulant, wherein edges of the encapsulant are flush with the side surfaces of the heat sink, and the encapsulant has a smaller area than that of the substrate.

2. The thermally enhanced semiconductor package of claim 1, wherein the substrate is selected from the group consisting of a BGA (ball grid array) substrate and a LGA (land grid array) substrate.

3. The thermally enhanced semiconductor package of claim 1, wherein the semiconductor chip is electrically connected to the substrate by a plurality of bonding wires.

4. The thermally enhanced semiconductor package of claim 3, wherein the bottom surface of the heat sink is formed with a contact portion extended to an upper surface of the semiconductor chip, such that the bonding wires are kept from coming into contact with the heat sink by means of the contact portion.

5. The thermally enhanced semiconductor package of claim 1, wherein the semiconductor chip is electrically connected to the substrate in a flip-chip manner.

6. The thermally enhanced semiconductor package of claim 1, wherein a recessed portion is formed substantially at an edge position of the bottom surface of the heat sink.

7. The thermally enhanced semiconductor package of claim 1, wherein an adhesion-enhanced portion is formed on the bottom surface of the heat sink at a position in contact with the encapsulant.

8. The thermally enhanced semiconductor package of claim 7, wherein the adhesion-enhanced portion is selected from the group consisting of a convex-concave structure, a roughened structure, and a structure subjected to black oxide.

9. The thermally enhanced semiconductor package of claim 1, further comprising a plurality of conductive elements mounted to a lower surface of the substrate, for allowing the semiconductor chip to be electrically connected to an external device via the conductive elements.

10. The thermally enhanced semiconductor package of claim 9, wherein the conductive elements are solder balls.

11. The thermally enhanced semiconductor package of claim 1, further comprising an interface layer formed on the top surface of the heat sink.

12. The thermally enhanced semiconductor package of claim 11, wherein the interface layer is made of a metal having poor adhesion with the encapsulant.

13. The thermally enhanced semiconductor package of claim 12, wherein the metal is selected from the group consisting of gold and chromium.

14. A fabrication method of a thermally enhanced semiconductor package, comprising the steps of:
mounting and electrically connecting at least one semiconductor chip to an upper surface of a chip carrier on which a receiving plate having an opening corresponding in position to the semiconductor chip is mounted, wherein the semiconductor chip is received in the opening and mounted on the chip carrier;
attaching a heat sink via a bottom surface thereof to the semiconductor chip, with an interface layer being formed on a top surface of the heat sink;
performing a molding process to form an encapsulate for encapsulating the heat sink, the semiconductor chip and a portion of the receiving plate;
performing a cutting process along edges of the opening of the receiving plate to remove the receiving plate and a portion of the encapsulate formed on the receiving plate; and
removing a portion of the encapsulant formed on the interface layer on the heat sink.

15. The fabrication method of claim 14, further comprising mounting a plurality of conductive elements to a lower surface of the chip carrier, for allowing the semiconductor chip to be electrically connected to an external device via the conductive elements.

16. The fabrication method of claim 14, wherein the semiconductor package is fabricated in a batch-type manner such that a singulation process is performed after the molding process so as to form a plurality of individual package units.

17. The fabrication method of claim 16, wherein a plurality of conductive elements are mounted to a lower surface of the chip carrier before the singulation process.

18. The fabrication method of claim 16, wherein a plurality of conductive elements are mounted to a lower surface of the chip carrier after the singulation process.

19. The fabrication method of claim 14, wherein the semiconductor chip is electrically connected to the chip carrier by a plurality of bonding wires.

20. The fabrication method of claim 19, wherein the bottom surface of the heat sink is formed with a contact portion extended to an upper surface of the semiconductor chip, such that the bonding wires are kept from coming into contact with the heat sink by means of the contact portion.

21. The fabrication method of claim 14, wherein the semiconductor chip is electrically connected to the chip carrier in a flip-chip manner.

22. The fabrication method of claim 14, wherein the chip carrier is selected from the group consisting of a BGA substrate and a LGA substrate.

23. The fabrication method of claim 14, wherein the opening of the receiving plate has a size substantially equal to that of the fabricated semiconductor package.

24. The fabrication method of claim 14, wherein the heat sink has a size larger than that of the opening of the receiving plate.

25. The fabrication method of claim 14, wherein the heat sink is formed with an adhesion-enhanced portion on the bottom surface thereof at a position in contact with the encapsulant.

26. The fabrication method of claim 25, wherein the adhesion-enhanced portion is selected from the group consisting of a convex-concave structure, a roughened structure, and a structure subjected to a black oxide process.

27. The fabrication method of claim 14, wherein the heat sink is formed with a recessed portion substantially at an edge position of the bottom surface thereof to facilitate the cutting process.

28. The fabrication method of claim 14, wherein the encapsulant after the cutting process has a size smaller than that of the opening of the receiving plate.

29. The fabrication method of claim 14, wherein the encapsulant after the cutting process has a size equal to that of the opening of the receiving plate.

30. The fabrication method of claim 14, wherein the interface layer has greater adhesion with the heat sink than with the encapsulant, such that the interface layer remains on the heat sink after the portion of the encapsulant formed on the interface layer is removed.

31. The fabrication method of claim 30, wherein the interface layer is made of a material selected from the group consisting of gold and chromium.

32. The fabrication method of claim 14, wherein the interface layer has smaller adhesion with the heat sink than with the encapsulant, such that the interface layer is removed together with the encapsulant when the portion of the encapsulant formed on the interface layer is removed.

33. The fabrication method of claim 32, wherein the interface layer is a tape made of polyimide resin.

34. The fabrication method of claim 32, wherein the interface layer is a coating layer made of epoxy resin.
